(19) United States
(12) Patent Application Publication
(10) Pub. No.: US 2025/0006694 A1
(43) Pub. Date: Jan. 2, 2025

(54) HIGH-BANDWIDTH THREE-DIMENSIONAL (3D) DIE STACK

(71) Applicant: XILINX, INC., San Jose, CA (US)

(72) Inventors: Martin L. VOOGEL, Niwot, CO (US); Matthew H. KLEIN, Redwood City, CA (US)

(21) Appl. No.: 18/215,685

(22) Filed: Jun. 28, 2023

(51) Int. Cl. H01L 25/065; H01L 23/00; H01L 23/498

(52) U.S. Cl. CPC H01L 25/0652; H01L 23/49838; H01L 24/29; H01L 24/32; H01L 24/83; H01L 24/94; H01L 2224/29187; H01L 2224/32145; H01L 2224/83896; H01L 2224/94; H01L 2924/1431; H01L 2924/1432; H01L 2924/1433; H01L 2924/1436; H01L 2924/1437; H01L 2924/381

(57) ABSTRACT

Examples herein describe techniques for producing a three-dimensional (3D) die stack. The techniques include stacking a first die on top of a second die. The first die is offset from the second die in at least one of an x-direction and a y-direction, and a first routing sub-region of the first die aligns with a second routing sub-region of the second die. The techniques further include stacking a third die on top of the second die. The third die is offset from the second die in at least one of the x-direction and the y-direction, and a third routing sub-region of the third die aligns with a fourth routing sub-region of the second die.

### TECHNICAL FIELD

Examples of the present disclosure generally relate to integrated circuit (IC) devices, and more specifically, to a high-bandwidth 3D die stack.

### BACKGROUND

Increasingly, high-performance computing applications are implementing integrated circuit (IC) packaging techniques that enable multiple dice to communicate within a single package. In one such technique (commonly referred to as “2.5D” IC packaging), multiple dice are coupled to an interposer that includes several metal layers for routing signals between the dice. These techniques have been widely adopted by industry, but suffer from a number of drawbacks.

### SUMMARY

Techniques for producing a three-dimensional (3D) die stack. The techniques include stacking a first die on top of a second die. The first die is offset from the second die in at least one of an x-direction and a y-direction, and a first routing sub-region of the first die aligns with a second routing sub-region of the second die. The techniques further include stacking a third die on top of the second die. The third die is offset from the second die in at least one of the x-direction and the y-direction, and a third routing sub-region of the third die aligns with a fourth routing sub-region of the second die.

One example described herein is a 3D die stack. The 3D die stack includes a first die stacked on top of a second die. The first die is offset from the second die in at least one of an x-direction and a y-direction, and a first routing sub-region of the first die aligns with a second routing sub-region of the second die. The 3D die stack further includes a third die stacked on top of the second die. The third die is offset from the second die in at least one of the x-direction and the y-direction, and a third routing sub-region of the third die aligns with a fourth routing sub-region of the second die.

One example described herein is a computing system. The computing system includes a memory and a 3D die stack coupled to the memory. The 3D die stack includes a first die stacked on top of a second die. The first die is offset from the second die in at least one of an x-direction and a y-direction, and a first routing sub-region of the first die aligns with a second routing sub-region of the second die. The 3D die stack further includes a third die stacked on top of the second die. The third die is offset from the second die in at least one of the x-direction and the y-direction, and a third routing sub-region of the third die aligns with a fourth routing sub-region of the second die.

### BRIEF DESCRIPTION OF DRAWINGS

So that the manner in which the above recited features can be understood in detail, a more particular description, briefly summarized above, may be had by reference to example implementations, some of which are illustrated in the appended drawings. It is to be noted, however, that the appended drawings illustrate only typical example implementations and are therefore not to be considered limiting of its scope.

FIG. 1 is a block diagram of a SoC that includes a data processing engine array and programmable logic, according to an example.

FIG. 2 is a block diagram of a data processing engine in the data processing engine array, according to an example.

FIG. 3A illustrates a schematic cross-sectional view of a three-dimensional (3D) die stack including two PL die types, according to an example.

FIG. 3B illustrates an exploded top-level view of the 3D die stack of FIG. 3A.

FIG. 4 illustrates a schematic cross-sectional view of a 3D die stack including a single programmable logic (PL) die type, according to an example.

FIG. 5 illustrates multiple logic sub-regions included in each PL die.

FIGS. 6A-6C illustrate schematic cross-sectional views of different 3D die stacks including a first type of PL dice and/or a second type of PL dice, according to several examples.

FIGS. 6D-6O illustrate schematic cross-sectional views of different 3D die stacks including various types of dice, according to several examples.

FIG. 7 illustrates a technique for generating different types of heterogeneous dice by offsetting a single set of mask patterns, according to an example.

FIGS. 8 and 9 illustrate techniques for generating different types of heterogeneous dice by offsetting a single set of mask patterns and cutting the resulting die along the x-direction or the y-direction, according to several examples.

FIGS. 10A-10C illustrate a technique for generating large-scale 3D die stacks by offsetting a single set of mask patterns, according to an example.

FIG. 11 is a flowchart of a method for producing a 3D die stack, according to an example.

FIG. 12 is a flowchart of a method for producing a 3D die stack by stepping a set of mask patterns in an offset manner, according to an example.

To facilitate understanding, identical reference numerals have been used, where possible, to designate identical elements that are common to the figures. It is contemplated that elements of one example may be beneficially incorporated in other examples.

### DETAILED DESCRIPTION

Various features are described hereinafter with reference to the figures. It should be noted that the figures may or may not be drawn to scale and that the elements of similar structures or functions are represented by like reference numerals throughout the figures. It should be noted that the figures are only intended to facilitate the description of the features. They are not intended as an exhaustive description or as a limitation on the scope of the claims. In addition, an illustrated example need not have all the aspects or advantages shown. An aspect or an advantage described in conjunction with a particular example is not necessarily limited to that example and can be practiced in any other examples even if not so illustrated, or if not so explicitly described.

Examples herein describe techniques for producing high-bandwidth three-dimensional (3D) die stacks. In various embodiments, the high-bandwidth 3D die stack techniques disclosed herein may be implemented to connect dice in an offset manner, such that adjacent dice (or any other dice in the die stack) can communicate via one or more dice disposed in a layer positioned above and/or below the adjacent dice. Because each die may include 15+ metal layers, and because the dice are connected to one another at a much finer pitch (e.g., less than 10 micron pitch) than conventional interposer techniques, lateral communication bandwidth between dice is greatly increased. Additionally, the resulting 3D die stack can be coupled directly to a PCB, eliminating the need for an interposer and therefore reducing packaging size, cost, and complexity. By contrast, conventional techniques require an interposer to build products larger than a mono reticle size. Conventional techniques that do not require an interposer typically utilize wires that cross unprocessed regions of a wafer (e.g., scribes) in wafer scale integration, which results in reduced bandwidth to allow for stitching.

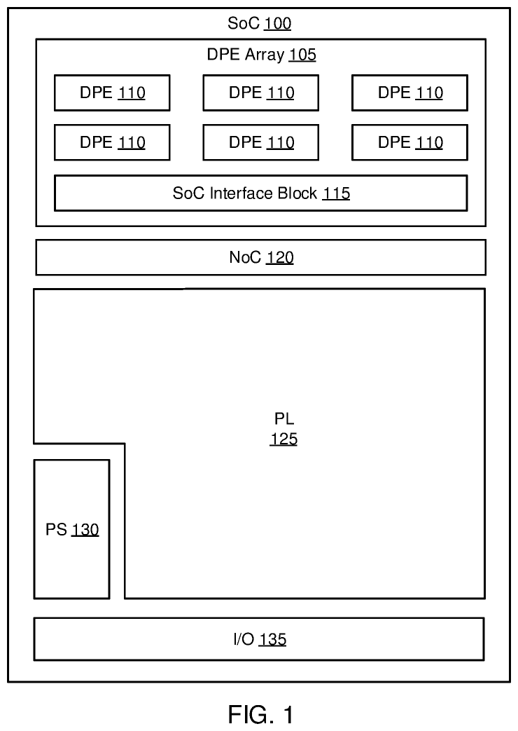

FIG. 1 is a block diagram of a SoC 100 that includes a data processing engine (DPE) array 105 and programmable logic (PL) 125, according to an example. The DPE array 105 includes a plurality of DPEs 110 which may be arranged in a grid, cluster, or checkerboard pattern in the SoC 100. Although FIG. 1 illustrates arranging the DPEs 110 in a 2D array with rows and columns, the embodiments are not limited to this arrangement. Further, the array 105 can be any size and have any number of rows and columns formed by the DPEs 110.

In one embodiment, the DPEs 110 are identical. That is, each of the DPEs 110 (also referred to as tiles or blocks) may have the same hardware components or circuitry. Further, the embodiments herein are not limited to DPEs 110. Instead, the SoC 100 can include an array of any kind of processing elements, for example, the DPEs 110 could be digital signal processing engines, cryptographic engines, Forward Error Correction (FEC) engines, or other specialized hardware for performing one or more specialized tasks.

In FIG. 1, the array 105 includes DPEs 110 that are all the same type (e.g., a homogeneous array). However, in another embodiment, the array 105 may include different types of engines. For example, the array 105 may include digital signal processing engines, cryptographic engines, graphic processing engines, and the like. Regardless of whether the array 105 is homogenous or heterogeneous, the DPEs 110 can include direct connections between DPEs 110 which permit the DPEs 110 to transfer data directly as described in more detail below.

In one embodiment, the DPEs 110 are formed from software-configurable hardened logic (i.e., are hardened). One advantage of doing so is that the DPEs 110 may take up less space in the SoC 100 relative to using programmable logic to form the hardware elements in the DPEs 110. That is, using hardened logic circuitry to form the hardware elements in the DPE 110 such as program memories, an instruction fetch/decode unit, fixed-point vector units, floating-point vector units, arithmetic logic units (ALUs), multiply accumulators (MAC), and the like can significantly reduce the footprint of the array 105 in the SoC 100. Although the DPEs 110 may be hardened, this does not mean the DPEs 110 are not programmable. That is, the DPEs 110 can be configured when the SoC 100 is powered on or rebooted to perform different functions or tasks.

The DPE array 105 also includes a SoC interface block 115 (also referred to as a shim) that serves as a communication interface between the DPEs 110 and other hardware components in the SoC 100. In this example, the SoC 100 includes a network on chip (NoC) 120 that is communicatively coupled to the SoC interface block 115. Although not shown, the NoC 120 may extend throughout the SoC 100 to permit the various components in the SoC 100 to communicate with each other. For example, in one physical implementation, the DPE array 105 may be disposed in an upper right portion of the integrated circuit forming the SoC 100. However, using the NoC 120, the array 105 can nonetheless communicate with, for example, PL 125, a processor subsystem (PS) 130, input/output (I/O) 135, or memory controller (MC) 140 which may be disposed at different locations throughout the SoC 100.

In addition to providing an interface between the DPEs 110 and the NoC 120, the SoC interface block 115 may also provide a connection directly to a communication fabric in the PL 125. In this example, the PL 125 and the DPEs 110 form a heterogeneous processing system since some of the kernels in a dataflow graph may be assigned to the DPEs 110 for execution while others are assigned to the PL 125. While FIG. 1 illustrates a heterogeneous processing system in a SoC, in other examples. the heterogeneous processing system can include multiple devices or chips. For example, the heterogeneous processing system could include two FPGAs or other specialized accelerator chips that are either the same type or different types. Further, the heterogeneous processing system could include two communicatively coupled SoCs.

In one embodiment, the SoC interface block 115 includes separate hardware components for communicatively coupling the DPEs 110 to the NoC 120 and to the PL 125 that is disposed near the array 105 in the SoC 100. In one embodiment, the SoC interface block 115 can stream data directly to a fabric for the PL 125. For example, the PL 125 may include an FPGA fabric which the SoC interface block 115 can stream data into, and receive data from, without using the NoC 120. That is, the circuit switching and packet switching described herein can be used to communicatively couple the DPEs 110 to the SoC interface block 115 and also to the other hardware blocks in the SoC 100. In another example, SoC interface block 115 may be implemented in a different die than the DPEs 110. In yet another example, DPE array 105 and at least one subsystem may be implemented in a same die while other subsystems and/or other DPE arrays are implemented in other dies. Moreover, the streaming interconnect and routing described herein with respect to the DPEs 110 in the DPE array 105 can also apply to data routed through the SoC interface block 115.

Although FIG. 1 illustrates PL 125 as one contiguous block, the SoC 100 may include multiple blocks of PL 125 (also referred to as logic sub-regions) that can be disposed adjacent to one another and/or at different locations in the SoC 100, Each logic sub-region (also referred to as a fabric sub-region) may include a set of configuration logic blocks (CLBs) that can include look-up tables (LUTs). In some embodiments, each logic sub-region is driven by a separate clock signal. In such embodiments, the logic sub-regions may be referred to as “clock regions.” PL 125 may include hardware elements that form a field programmable gate array (FPGA). However, in other embodiments, the SoC 100 may not include any PL 125—e.g., the SoC 100 may be an application-specific integrated circuit (ASIC).

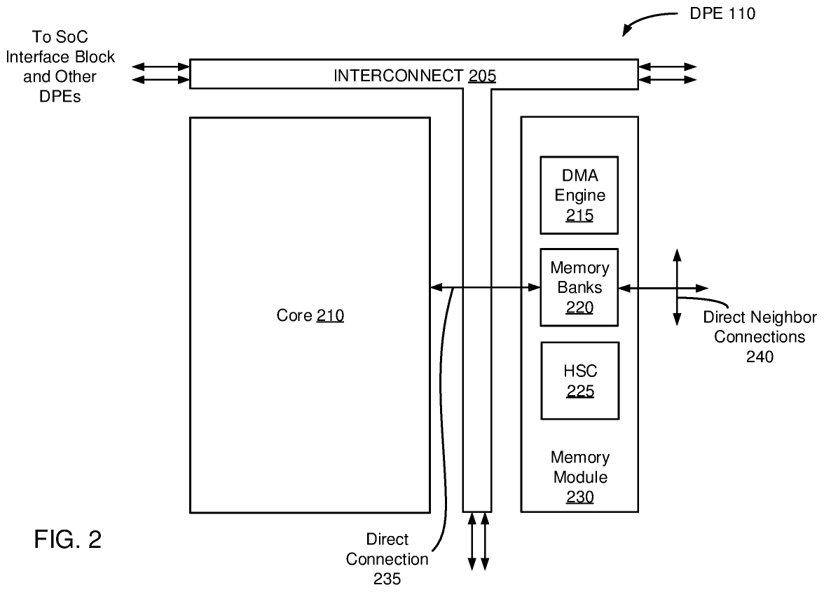

FIG. 2 is a block diagram of a DPE 110 in the DPE array 105 illustrated in FIG. 1, according to an example. The DPE 110 includes an interconnect 205, a core 210, and a memory module 230. The interconnect 205 permits data to be transferred from the core 210 and the memory module 230 to different cores in the array 105. That is, the interconnect 205 in each of the DPEs 110 may be connected to each other so that data can be transferred north and south (e.g., up and down) as well as east and west (e.g., right and left) in the array of DPEs 110.

Referring back to FIG. 1, in one embodiment, the DPEs 110 in the upper row of the array 105 rely on the interconnects 205 in the DPEs 110 in the lower row to communicate with the SoC interface block 115. For example, to transmit data to the SoC interface block 115, a core 210 in a DPE 110 in the upper row transmits data to its interconnect 205 which is in turn communicatively coupled to the interconnect 205 in the DPE 110 in the lower row. The interconnect 205 in the lower row is connected to the SoC interface block 115. The process may be reversed where data intended for a DPE 110 in the upper row is first transmitted from the SoC interface block 115 to the interconnect 205 in the lower row and then to the interconnect 205 in the upper row that is the target DPE 110. In this manner, DPEs 110 in the upper rows may rely on the interconnects 205 in the DPEs 110 in the lower rows to transmit data to and receive data from the SoC interface block 115.

In one embodiment, the interconnect 205 includes a configurable switching network that permits the user to determine how data is routed through the interconnect 205. In one embodiment, unlike in a packet routing network, the interconnect 205 may form streaming point-to-point connections. That is, the streaming connections and streaming interconnects (not shown in FIG. 2) in the interconnect 205 may form routes from the core 210 and the memory module 230 to the neighboring DPEs 110 or the SoC interface block 115. Once configured, the core 210 and the memory module 230 can transmit and receive streaming data along those routes. In one embodiment, the interconnect 205 is configured using the Advanced Extensible Interface (AXI) 4 Streaming protocol.

In addition to forming a streaming network, the interconnect 205 may include a separate network for programming or configuring the hardware elements in the DPE 110. Although not shown, the interconnect 205 may include a memory mapped interconnect which includes different connections and switch elements used to set values of configuration registers in the DPE 110 that alter or set functions of the streaming network, the core 210, and the memory module 230.

In one embodiment, streaming interconnects (or network) in the interconnect 205 support two different modes of operation referred to herein as circuit switching and packet switching. In one embodiment, both of these modes are part of, or compatible with, the same streaming protocol—e.g., an AXI Streaming protocol. Circuit switching relies on reserved point-to-point communication paths between a source DPE 110 to one or more destination DPEs 110. In one embodiment, the point-to-point communication path used when performing circuit switching in the interconnect 205 is not shared with other streams (regardless whether those streams are circuit switched or packet switched). However, when transmitting streaming data between two or more DPEs 110 using packet-switching, the same physical wires can be shared with other logical streams.

The core 210 may include hardware elements for processing digital signals. For example, the core 210 may be used to process signals related to wireless communication, radar, vector operations, machine learning applications, and the like. As such, the core 210 may include program memories, an instruction fetch/decode unit, fixed-point vector units, floating-point vector units, arithmetic logic units (ALUs), multiply accumulators (MAC), and the like. However, as mentioned above, this disclosure is not limited to DPEs 110. The hardware elements in the core 210 may change depending on the engine type. That is, the cores in a digital signal processing engine, cryptographic engine, or FEC may be different.

The memory module 230 includes a DMA engine 215, memory banks 220, and hardware synchronization circuitry (HSC) 225 or other type of hardware synchronization block. In one embodiment, the DMA engine 215 enables data to be received by, and transmitted to, the interconnect 205. That is, the DMA engine 215 may be used to perform DMA reads and write to the memory banks 220 using data received via the interconnect 205 from the SoC interface block or other DPEs 110 in the array.

The memory banks 220 can include any number of physical memory elements (e.g., SRAM). For example, the memory module 230 may be include 4, 8, 16, 32, etc. different memory banks 220. In this embodiment, the core 210 has a direct connection 235 to the memory banks 220. Stated differently, the core 210 can write data to, or read data from, the memory banks 220 without using the interconnect 205. That is, the direct connection 235 may be separate from the interconnect 205. In one embodiment, one or more wires in the direct connection 235 communicatively couple the core 210 to a memory interface in the memory module 230 which is in turn coupled to the memory banks 220.

In one embodiment, the memory module 230 also has direct connections 240 to cores in neighboring DPEs 110. Put differently, a neighboring DPE in the array can read data from, or write data into, the memory banks 220 using the direct neighbor connections 240 without relying on their interconnects or the interconnect 205 shown in FIG. 2. The HSC 225 can be used to govern or protect access to the memory banks 220. In one embodiment, before the core 210 or a core in a neighboring DPE can read data from, or write data into, the memory banks 220, the core (or the DMA engine 215) requests a lock acquire to the HSC 225 when it wants to read or write to the memory banks 220 (e.g., when the core/DMA engine want to “own” a buffer, which is an assigned portion of the memory banks 220. If the core or DMA engine does not acquire the lock, the HSC 225 will stall (e.g., stop) the core or DMA engine from accessing the memory banks 220. When the core or DMA engine is done with the buffer, they release the lock to the HSC 225. In one embodiment, the HSC 225 synchronizes the DMA engine 215 and core 210 in the same DPE 110 (e.g., memory banks 220 in one DPE 110 are shared between the DMA engine 215 and the core 210). Once the write is complete, the core (or the DMA engine 215) can release the lock which permits cores in neighboring DPEs to read the data.

### High-Bandwidth Three-Dimensional (3D) Die Stack

Increasingly, high-performance computing applications are implementing integrated circuit (IC) packaging techniques that enable multiple dice to communicate within a single package. In one such technique (commonly referred to as “2.5D” IC packaging), multiple dice are coupled to an interposer that includes several metal layers for routing signals between the dice. These techniques have been widely adopted by industry, but suffer from a number of drawbacks.

For example, microbumps that are implemented to attach dice to an interposer are commonly at a pitch of 50-150 microns, limiting the number of connections that can be formed between each die and the interposer for a given surface area. Additionally, interposers commonly include only three layers of metal, as compared to 15+ metal layers in a typical monolithic die. Consequently, communication bandwidth from each die to the interposer—and therefore communication bandwidth between dice attached to the interposer—is greatly reduced as compared to the bandwidth that is available within each monolithic die, resulting in data routing bottlenecks.

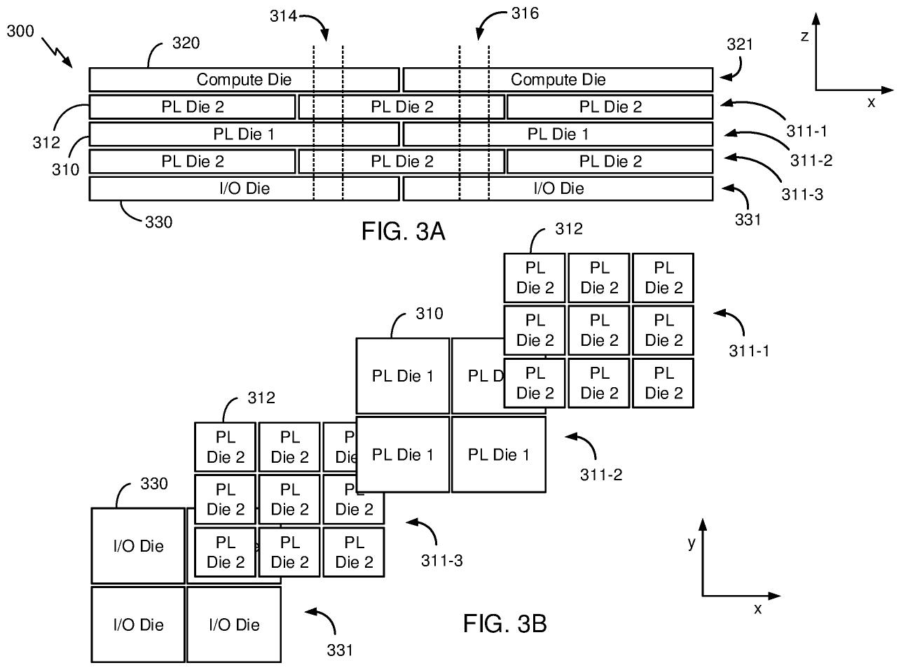

In various embodiments, the high-bandwidth 3D die stack techniques disclosed herein may be implemented to connect dice in an offset manner, such that adjacent dice (or any other dice in the die stack) can communicate via one or more dice disposed in a layer positioned above and/or below the adjacent dice. Because each die may include 15+ layers of metal, and because the dice are connected to one another at a much finer pitch (e.g., less than 10-micron pitch) than conventional interposer techniques, lateral communication bandwidth between dice is greatly increased. In some embodiments, wafer-on-wafer stacking enables dice included in each wafer to be vertically connected at an even finer pitch (e.g., less than a 5-micron pitch, such as less than a 1-micron pitch) relative to techniques for stacking die-on-die or die-on-wafer, which may allow a pitch down to 10 microns. Additionally, the resulting 3D die stack can be coupled directly to a PCB, eliminating the need for an interposer and therefore reducing packaging size, cost, and complexity. Such techniques are described below in further detail in conjunction with FIGS. 3A-3B, 4, 5, 6A-6L, and 7-12.

FIG. 3A illustrates a schematic cross-sectional view of a three-dimensional (3D) die stack 300 including two PL die types, according to an example. FIG. 3B illustrates an exploded top-level view of the 3D die stack 300 of FIG. 3A. The 3D die stack 300 includes a first type of PL dice 310, a second type of PL dice 312, compute dice 320, and I/O dice 330. The 3D die stack 300 may be electrically coupled to a PCB (not shown). In some embodiments, compute dice 320 include a DPE array 105 having one or more DPEs 110 and/or any other relevant circuitry included in SoC 100. I/O dice 330 may include I/O 135 and/or any other relevant circuitry included in SoC 100.

In various embodiments, each layer of dice may include a single wafer that forms vertical connections via wafer-on-wafer bonding, or one or more layers of dice may be formed from a single wafer, while one or more different layers may include separate and distinct dice that are not part of a single wafer and which are bonded to a wafer via die-on-wafer bonding. For example, the layer of compute dice 320 may be formed on a single compute wafer 321, the layer of I/O dice 330 may be formed on a single I/O wafer 331, and each layer of PL dice 310, 312 (e.g., the upper layer of PL dice 312, the middle layer of PL dice 310, and the lower layer of PL dice 312) may be formed on a single PL wafer 311 (e.g., including three total PL wafers 311-1, 311-2, 311-3 in 3D die stack 300). Although FIG. 3B illustrates a rectangular wafer shape, in various embodiments, the shape of each wafer may any shape (e.g., round). Additionally, each wafer may include white space (not shown) in which no dice are fabricated.

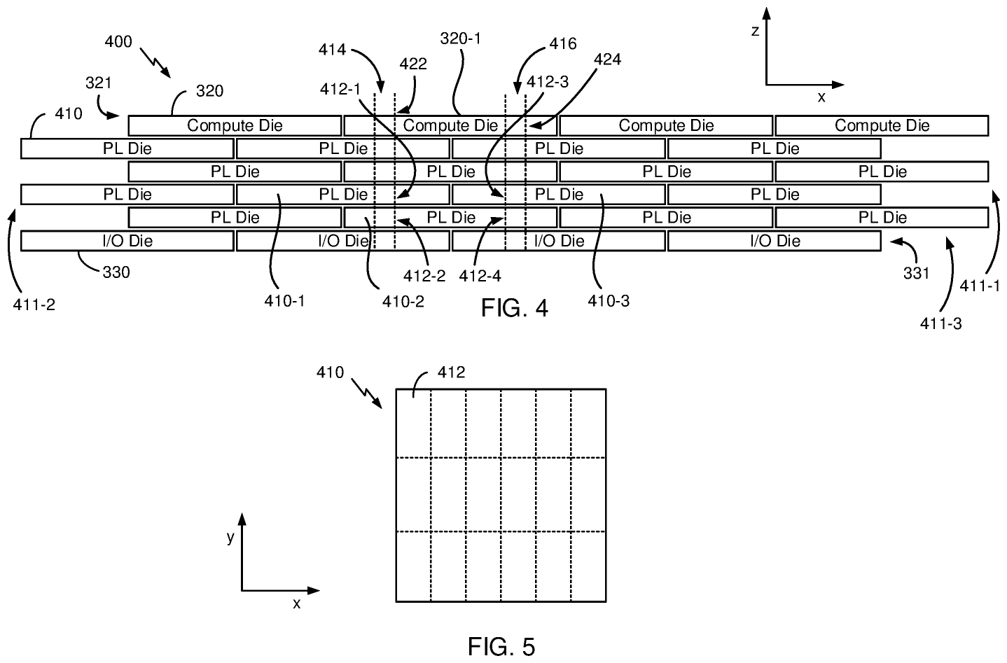

In general, the first type of PL dice 310 and the second type of PL dice 312 may include similar types of circuitry as described below with respect to the PL dice 410 of FIGS. 4 and 5, but may be fabricated via different sets of mask patterns having different circuitry, dimensions, and/or sizes. As further described below in conjunction with FIGS. 4 and 5, logic sub-region(s) of each PL die 310, 312 may be in vertical alignment 314. 316 with logic sub-regions of other PL dice 310, 312 and/or corresponding regions of compute dice 320. Although FIG. 3A illustrates three layers of PL dice 310, 312, any number of layers each having any number of PL dice 310, 312 may be implemented in the 3D die stack 300.

As shown, the second type of PL dice 312 have smaller dimensions than the first type of PL dice 310. In some embodiments, this configuration enables the PL dice 310, 312 to be stacked on top of one another in an offset manner—enabling high-bandwidth communications through the PL dice 310, 312—while still aligning the edges of the dice 310, 312 along a perimeter of the 3D die stack 300. Such a configuration provides a more practical IC package design while also avoiding cutting through active silicon regions of a given die. Such a configuration may also improve the yield of 3D die stacks 300 by providing additional redundancy in the layers that includes the second type of PL dice 312. For example, by connecting more than one PL die 312 between each pair of PL dice 310 included in a given layer, connectivity between two PL dice 310 may be retained even if one of the PL dice 312 is faulty.

FIG. 4 illustrates a schematic cross-sectional view of a 3D die stack 400 including a single programmable logic (PL) die type, according to an example. As shown, the 3D die stack 400 includes PL dice 410, compute dice 320, and I/O dice 330. Although FIG. 4 illustrates three layers of PL dice 410, any number of layers of PL dice 410 may be implemented in the 3D die stack 400.

In various embodiments, each layer of dice includes a single wafer, such that 3D die stack 400 is formed via multiple wafer-on-wafer bonding processes (e.g., at a pitch of less than 5 microns, such as less than 1 micron). For example, the layer of compute dice 320 may be formed on a single compute wafer 321, the layer of I/O dice 330 may be formed on a single I/O wafer 331, and each layer of PL dice 410 may be formed on a single PL wafer 411 (e.g., including three total PL wafers 411-1, 411-2, 411-3 in 3D die stack 400). In some embodiments, less than all of the layers of dice are formed from single wafers. For example, one or more layers of the 3D die stack 400 may be formed from a single wafer, and one or more different layers may include separate and distinct dice that are not part of a single wafer, and which are bonded to a wafer via die-on-wafer bonding. Although FIG. 4 illustrates gaps between layers along the edges of 3D die stack 400, in various embodiments, the edges of each layer (e.g., the edges of each wafer) may be aligned, such that the edges of the 3D die stack 400 are flush. For example, each wafer may include white space (not shown) in which no dice are fabricated, enabling the edges of the layers to be aligned.

As shown in FIG. 5, each PL die 410 (and also PL die 310, 312, 610, 612, etc.) may include multiple logic sub-regions 412 (also referred to herein as “fabric sub-regions” or “clock regions”). In various embodiments, each PL die 410 (and also PL die 310, 312, 610, 612, etc.) may include hardware elements (e.g., circuitry) that are programmable or configurable. In one embodiment, the PL (e.g., the PL 125) in the PL dies include programmable logic fabrics. The fabrics may be part of a field programmable gate array (FPGA). In one embodiment, the PL is arranged in CLBs (e.g., programmable logic blocks) that may be contiguous or non-contiguous and can include programmable interconnects and lookup tables (LUTs).

3D die stack 400 includes multiple layers of PL dice 410, where the PL dice 410 included in a particular layer are offset, in at least one of an x-direction and a y-direction, from the PL dice 410 that are included in a layer above or below that particular layer. In some embodiments, a first PL die 410-1 included in a first layer is stacked on top of and offset from a second PL die 410-2 included in a second layer positioned below the first layer, such that there is vertical alignment 414 between a first logic sub-region 412 included in the first PL die 410-1 and at least a portion of a second logic sub-region 412 included in the second PL die 410-2. Additionally, in some embodiments, a third PL die 410-3 included in the first layer is stacked on top of and offset from the second PL die 410-2, such that there is vertical alignment 416 between a third logic sub-region 412-3 included in the third PL die 410-3 and at least a portion of a fourth logic sub-region 412-4 included in the second PL die 410-2. Although only two regions of vertical alignment 414, 416 are shown in FIG. 4 for clarity and ease of illustration, in various embodiments, any number of regions of vertical alignment may be implemented in any of the 3D die stacks described herein. For example, in some embodiments, each PL die 410 includes at least one logic sub-region 412 that is vertically aligned with a logic sub-region 412 (or region 422) in every PL die 410 (or compute die 320) that is coupled to a top or a bottom of the PL die 410.

As shown in FIG. 4, PL dice 410 included in a particular layer are offset, by half a die size in the x-direction, from the PL dice 410 that are included in a layer above or below that particular layer. In some embodiments, some or all of the PL dice 410 included in a particular layer are also offset, in the y-direction (e.g., by half a die size, by a quarter die size, etc.), from the PL dice 410 that are included in a layer above or below that particular layer. In other embodiments, edges of some or all of the PL dice 410 included in a particular layer are aligned, in the y-direction, with edges of the PL dice 410 that are included in a layer above or below that particular layer.

As described above, this configuration provides high-bandwidth connectivity between multiple PL dice 410, including adjacent PL dice 410 (e.g., the first PL die 410-1 and the third PL die 410-3). For example, a first routing sub-region (e.g., first logic sub-region 412-1) may be pitch-matched to a second routing sub-region (e.g., second logic sub-region 412-2), and high-density through-silicon vias (TSVs) included in the first logic sub-region 412-1 may be electrically connected to the second logic sub-region 412-2. Similarly, a third routing sub-region (e.g., third logic sub-region 412-3) may be pitch-matched to a fourth routing sub-region (e.g., fourth logic sub-region 412-4), and high-density through-silicon vias (TSVs) included in the third logic sub-region 412-3 may be electrically connected to the fourth logic sub-region 412-4. A communication path is thus formed through the second PL die 410-2, to enable high-bandwidth lateral connectivity between the first PL die 410-1 and the third PL die 410-3.

In some embodiments, regions of the programmable logic (e.g., FPGA circuitry) included in each PL die 410 comprise a regular, repeating circuit pattern that is substantially uniform across a region of the PL die 410. This regularity enables high-density, vertical connections (e.g., in a z-direction) to be formed between PL dice 410. For example, the first PL die 410-1 and the third PL die 410-3 may include such regular, repeating circuitry that is hybrid oxide bonded to corresponding circuitry on top of the second PL die 410-2. This hybrid oxide bonding (or similar technique for electrically connecting the PL dice) may be performed at a pitch of less than 10 microns, such as less than 5 microns, such as less than 1 micron. Accordingly, although each PL die 410 may be smaller than the size of a reticle—and may be fabricated with a single set of mask patterns—the resulting 3D die stack 400 is significantly larger than a reticle size (e.g., 2×2 dice, 3×3 dice, 4×4 dice, 10×10 dice, wafer-scale, or larger) while still enabling connectivity between dice at a bandwidth that is substantially the same as or similar to the bandwidth of communication within a monolithic die.

In some embodiments, 3D die stack 400 further includes one or more compute dice 320 disposed on top of (or below or between) one or more PL dice 410 layers, and/or one or more I/O dice 330 disposed below (or on top of or between) one or more PL dice 410 layers. For example, as shown in FIG. 4, compute die 320-1 may be stacked on top of and offset from the first PL die 410-1 and the third PL die 410-3. Optionally, one or more layers of PL dice 410 may be disposed between the compute die 320-1 (or compute dice 320) and the layer in which the first PL die 410-1 and the third PL die 410-3 are disposed, or the compute die 320-1 (or compute dice 320) may be stacked directly on and bonded directly to the first PL die 410-1 and the third PL die 410-3.

In order to provide high-bandwidth connectivity between compute die 320-1 and the PL dice 410, a first region of 422 of compute die 320-1 (e.g., including programmable logic, routing circuitry, FPGA circuitry, NoC 120, etc.) may be aligned with the first routing sub-region (e.g., the first logic sub-region 412-1) and the second routing sub-region (e.g., the second logic sub-region 412-2). Similarly, a routing region of 424 of compute die 320-1 (e.g., including programmable logic, routing circuitry, FPGA circuitry, NoC 120, etc.) may be aligned with the third routing sub-region (e.g., the third logic sub-region 412-3) and the fourth routing sub-region (e.g., the fourth logic sub-region 412-4). Accordingly, one or more cores (e.g., DPEs 110) included in the compute dice 320 are provided with high-bandwidth connectivity to the PL dice 410, I/O dice 330, and/or other compute dice 320.

As shown in FIG. 4, the PL dice 410 may be offset from and stacked on top of one or more I/O dice 330. This configuration provides high-bandwidth connectivity between any PL die 410 and any I/O die 330 (e.g., via one or more PL dice 410). This configuration may further provide high-bandwidth connectivity between different I/O dice 330 (e.g., via one or more PL dice 410).

In some embodiments, the communications redundancy provided by the configuration shown in FIG. 4 enables a level of device functionality to be retained even if one or more defective die are included in the 3D die stack 400 (or in any other 3D die stack configuration described herein). For example, if a portion of the second PL die 410-2 is defective, and the defect prevents the first PL die 410-1 stacked on top of the second PL die 410-2 from routing communications through the first PL die 410-1, then the second PL die 410-2 may instead route communications between one or more different PL die 410 in a layer above or below the second PL die 410. Accordingly, 3D die stacks having one or more faulty dice may be salvaged and instead included in a lower market segment, improving overall device yield.

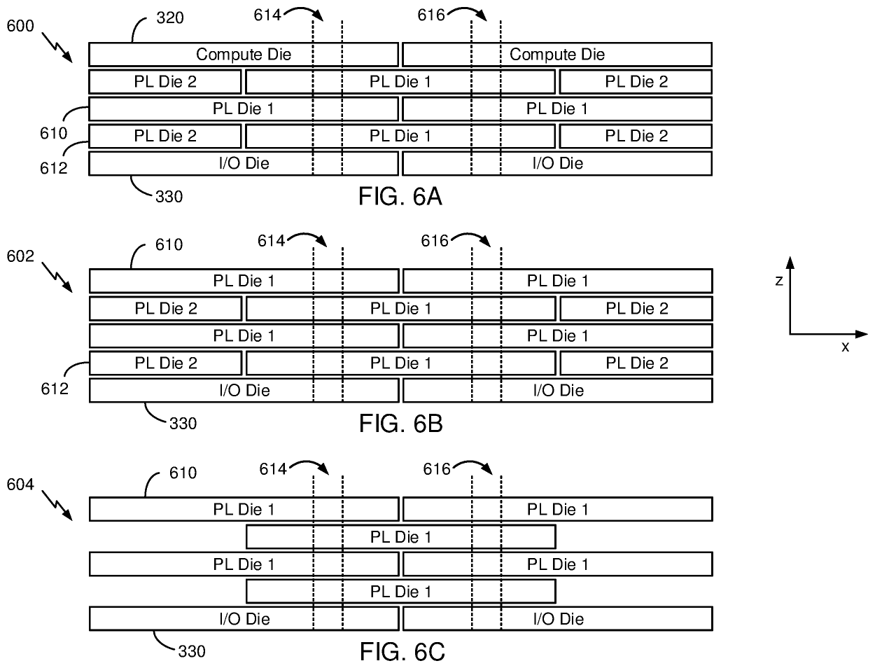

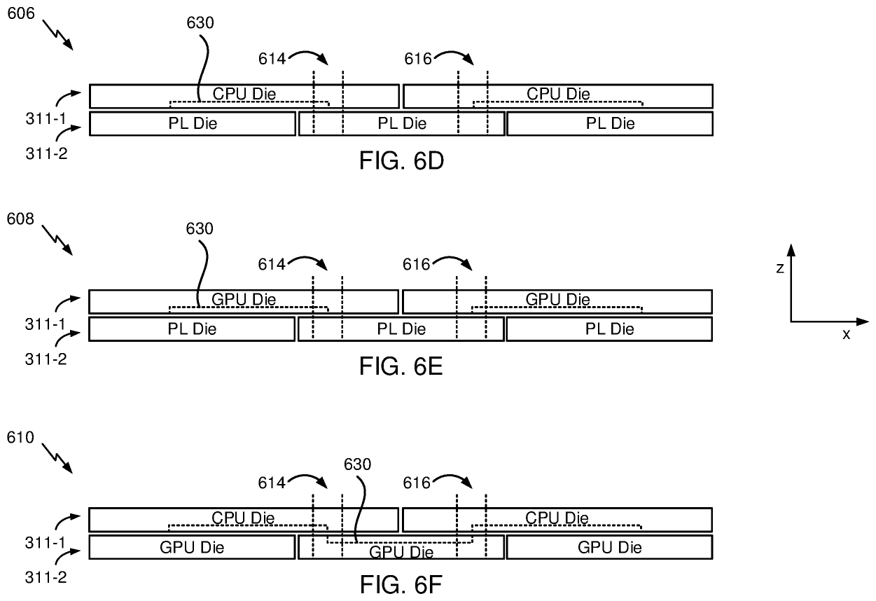

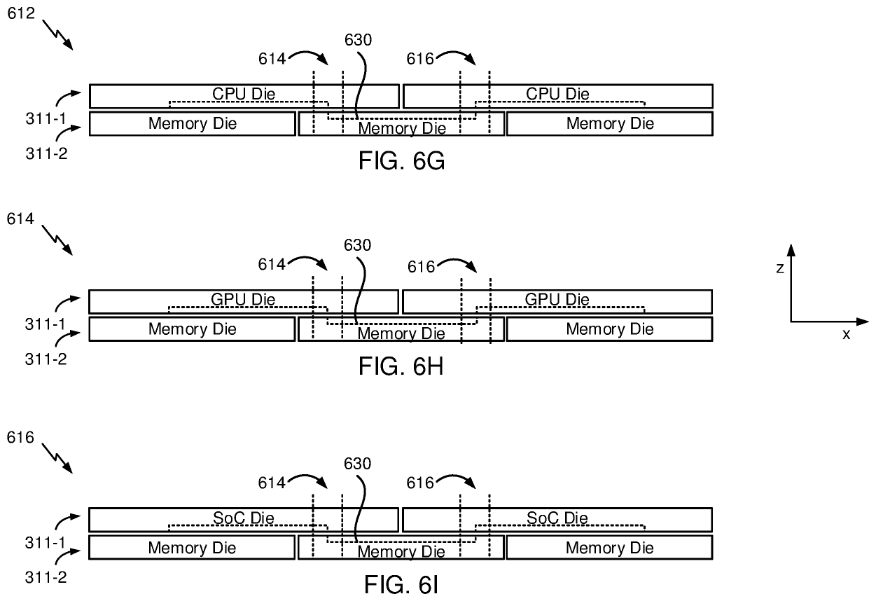

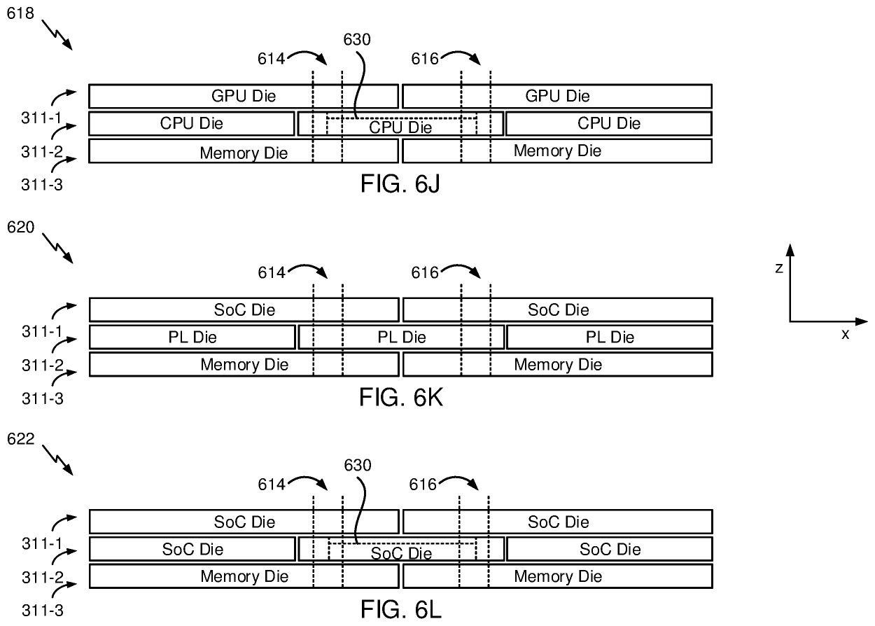

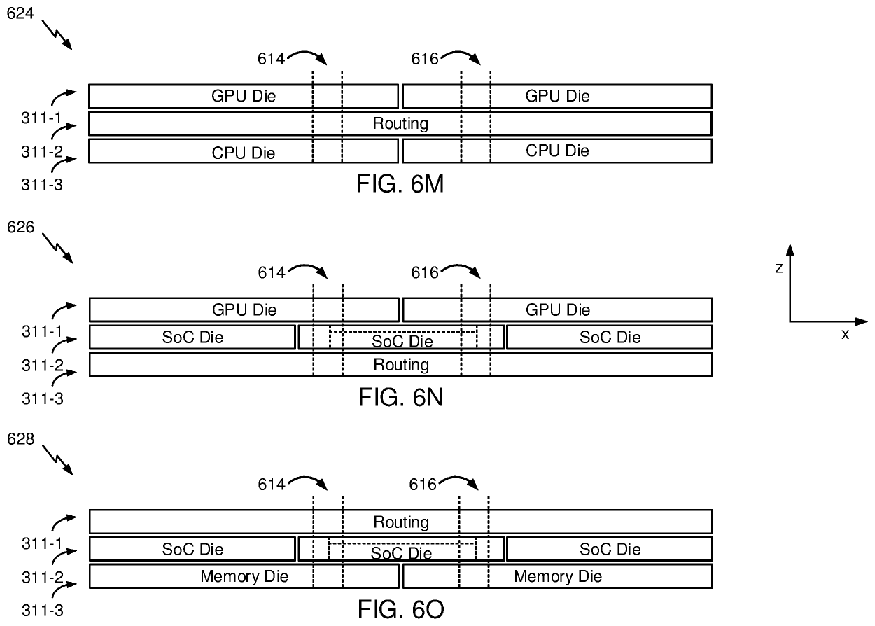

FIGS. 6A-6C illustrate schematic cross-sectional views of different 3D die stacks 600, 602, 604 including a first type of PL dice 610 and/or a second type of PL dice 612, according to several examples. As shown in FIGS. 6A and 6B, the second type of PL dice 612 may have a dimension in the x-direction that is half of the corresponding dimension of the first type of PL dice 610. Accordingly, both the first type of PL dice 610 and the second type of PL dice 612 can be disposed in the same layer (e.g., at a 1:2 ratio), while still maintaining a total length in the x-direction that is substantially the same as the total length of an integer number of PL dice 610. As described above, each 3D die stack 600, 602, 604 may include any number of regions of vertical alignment (e.g., regions of vertical alignment 614, 616) to enable high-bandwidth connectivity between PL dice 610, 612, compute dice 320, and/or I/O dice 330.

In various embodiments, each layer of dice shown in FIGS. 6A-6C may include a single wafer that forms vertical connections via wafer-on-wafer bonding, or one or more layers of dice may be formed from a single wafer, while one or more different layers may include separate and distinct dice that are not part of a single wafer and which are bonded to a wafer via die-on-wafer bonding. Additionally, although FIG. 6C illustrates gaps between layers along the edges of 3D die stack 604, in various embodiments, the edges of each layer (e.g., the edges of each wafer) may be aligned, such that the edges of the 3D die stack 604 are flush. For example, each wafer may include white space (not shown) in which no dice are fabricated, enabling the edges of the layers to be aligned.

FIGS. 6D-6O illustrate schematic cross-sectional views of different 3D die stacks including various types of dice, according to several examples. As shown in FIGS. 6D and 6E, a first layer 311-1 of CPU dice or GPU dice may be stacked on top of a second layer 311-2 of PL dice. Each 3D die stack 606, 608 may include any number of regions of vertical alignment (e.g., regions of vertical alignment 614, 616) at which routing sub-regions included CPU dice (or GPU dice) and PL dice align, enabling high-bandwidth connectivity between CPU dice (or GPU dice) and the PL dice.

As shown in FIG. 6F, a first layer 311-1 of CPU dice may be stacked on top of a second layer 311-2 of GPU dice. The 3D die stack 610 may include any number of regions of vertical alignment at which routing sub-regions included CPU dice and GPU dice align. For example, regions of vertical alignment 614, 616 enable high-bandwidth connectivity between the CPU dice and the GPU die on which the CPU dice are stacked via the routing circuitry 630 that is included in the GPU die and located within the regions of vertical alignment 614, 616. Although not illustrated, each die included in a given 3D die stack (e.g., die stack 610) may include similar routing circuitry 630 in regions of vertical alignment (e.g., 614, 616) between dice disposed on different layers 311 of the 3D die stack.

FIGS. 6G-6L illustrate schematic cross-sectional views of different 3D die stacks including different types of dice (e.g., CPU dice, GPU dice, SoC dice, PL dice, ASIC dice, I/O dice, compute dice, routing) stacked on top of a layer 311-3 of memory dice according to several examples. In various embodiments, one or more dice included in a particular layer 311 of a 3D die stack may share one or more memory die included in the layer of memory dice. Such a shared memory configuration enables faster and more efficient communication between dice included in the 3D die stack and enables a memory size allocated to one or more dice to be dynamically scaled in a more flexible manner. The memory dice may include any type of memory (e.g., DRAM, SRAM, or UltraRAM, also referred to as “URAM”).

FIGS. 6M-6O illustrate schematic cross-sectional views of different 3D die stacks including different types of dice (e.g., CPU dice, GPU dice, SoC dice, PL dice, ASIC dice, I/O dice, compute dice, routing) stacked on top of and/or below a routing layer 311 according to several examples. In various embodiments, the routing layer 311 may include a wafer on which static metal connections, static connections with metal and transistors, and/or programmable interconnect are fabricated. In some embodiments, the routing may be a continuous structure formed on a wafer, or the routing may be formed as discrete dice on a wafer, where the dice are separated by unprocessed regions of the wafer. Additionally, in some embodiments, the routing may be formed within a portion of any other type of die, and/or a routing die (or routing dice) may be included on a given wafer in conjunction with any other type(s) of dice. Although FIGS. 6M-6O illustrate specific combinations of dice, in various embodiments, any combination of dice (e.g., CPU dice, GPU dice, SoC dice, PL dice, ASIC dice, I/O dice, compute dice) may be stacked on top of and/or below a given routing layer 311.

Although specific types of dice are illustrated as being located in certain layers 311 of a given 3D die stack, in various embodiments, any type of die may be included in any layer 311 of the 3D die stack. For example, although the memory dice are included in layer 311-3 of 3D die stacks 612, 614, 616, 618, 620, 622, 628, in other embodiments, the memory dice may be included in layer 311-1 or 311-2, or in any other layer of the 3D die stacks. As shown, each type of die may include routing circuitry 630, enabling high-bandwidth connectivity between the die and dice that are located above and/or below the die. For example, as shown in FIGS. 6J, 6L, 6N, and 6O, routing circuitry 630 may provide high-bandwidth connectivity to dice and other routing both above and below the CPU die and the SoC die, respectively. Routing circuitry 630 may be implemented in any other type of die described herein.

For clarity of illustration, the example 3D die stacks shown in FIGS. 6D-61 include only two layers of dice, and the example 3D die stacks shown in FIGS. 6J-6O include only three layers of dice. However, in various embodiments, the 3D die stacks may include any number of layers having any type and/or combination of dice, including, without limitation, PL dice, CPU dice, GPU dice, SoC dice, ASIC dice, memory dice, I/O dice, compute dice, routing, etc. having any dimensions. For example, all of the layers included in a given 3D die stack shown in FIGS. 6D-6O may include dice having the same dimensions, or one or more layers within a given 3D die stack shown in FIGS. 6D-6O may include dice having different dimensions than the dice in other layers of the 3D die stack. Each layer of dice shown in FIGS. 6D-6O may include a single wafer that forms vertical connections via wafer-on-wafer bonding, or one or more layers of dice may be formed from a single wafer, while one or more different layers may include separate and distinct dice that are not part of a single wafer and which are bonded to a wafer via die-on-wafer bonding.

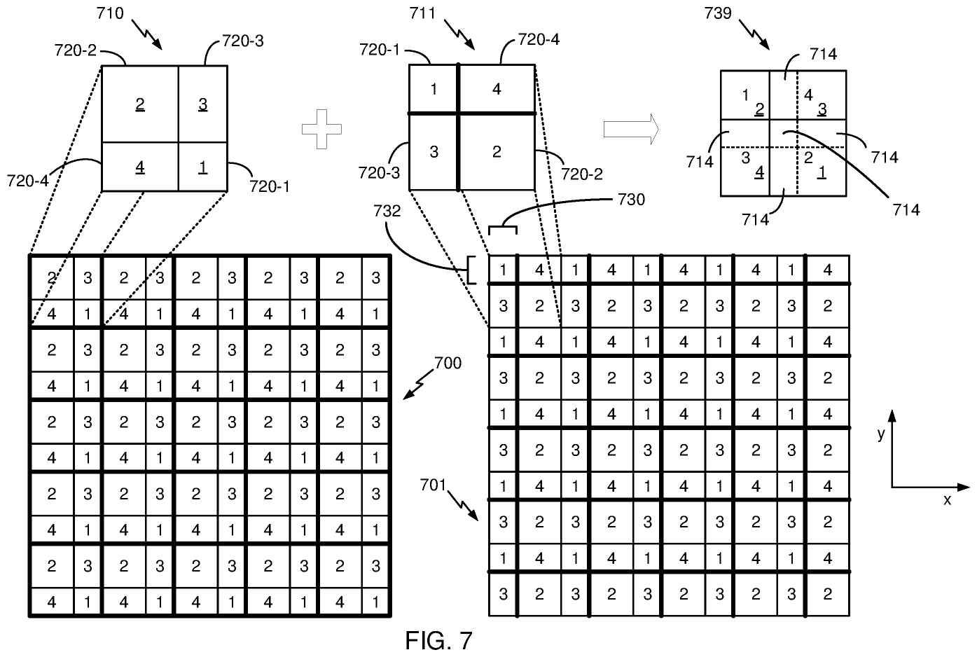

FIG. 7 illustrates a technique for generating different types of heterogeneous dice by offsetting a single set of mask patterns, according to an example. As shown, a first wafer 700 includes a first set of dice 710, where each die 710 comprises sub-components including a set of sub-dice 720-1 through 720-4. As further shown, a second wafer 701 includes a second set of dice 711, where each die 711 includes the same set of sub-dice 720-1 through 720-4 in a different configuration. In various embodiments, each sub-die 720 defined by the set of mask patterns is an independent IC, such as a SoC 100, PL die 310, compute die 320, or I/O die 330. Although the first wafer 700 and second wafer 701 are shown as having a rectangular shape for simplicity of illustration, any wafer shape or size (e.g., circular) may be implemented. For example, the rectangular regions of dice shown in FIGS. 7-9 and 10A may be part of a larger, circular wafer that is not shown in FIGS. 7-9 and 10A.

In various embodiments, the first set of dice 710 are produced by stepping a set of mask patterns across the first wafer 700 beginning at a first starting position, and the second set of dice 711 are produced by stepping the same set of mask patterns across the second wafer 701 beginning at a second starting position that is offset from the first starting position in at least one of the x-direction and the y-direction. In FIG. 7, the locations at which the set of mask patterns is stepped in each wafer 700, 701 are denoted by thicker vertical and horizontal lines. In some embodiments, the first set of dice 710 are produced by stepping a first mask set across the first wafer 700, and the second set of dice 711 are produced by stepping a second mask set across the second wafer 701, where the first mask set and the second mask set include substantially the same set of mask patterns. That is, in various embodiments, separate mask sets having the same set of mask patterns may be implemented.

As shown in FIG. 7, the set of mask patterns may be stepped across the second wafer 701 beginning at a second starting position that is offset 730 from the first starting position by approximately two-thirds of the total length of a die 710, 711 in the x-direction, and offset 732 from the first starting position by approximately two-thirds of the total length of a die 710, 711 in the y-direction. Consequently, each of die 710 and die 711 includes the same set of sub-dice 720, where the sub-dice 720 are in different positions relative to one another. As a result, when wafer 701 including dice 711 is stacked on top of wafer 700 including dice 710 and the bonded wafer stack 700, 701 is cut, the resulting 3D die stacks 739 include one or more vertical alignment regions 714 at which sub-dice 720 disposed at different corners of the dice 710, 711 overlap, enabling high-bandwidth communication (e.g., by hybrid oxide bonding logic sub-regions 312 and/or regions 322 included in the sub-dice 720) between the sub-dice 720. In FIG. 7, the lower sub-dice 720 included in 3D die stack 739 are denoted by underlining the sub-dice numbers (e.g., 1, 2, 3, 4), and the boundaries between the lower sub-dice 720 are denoted by dotted lines.

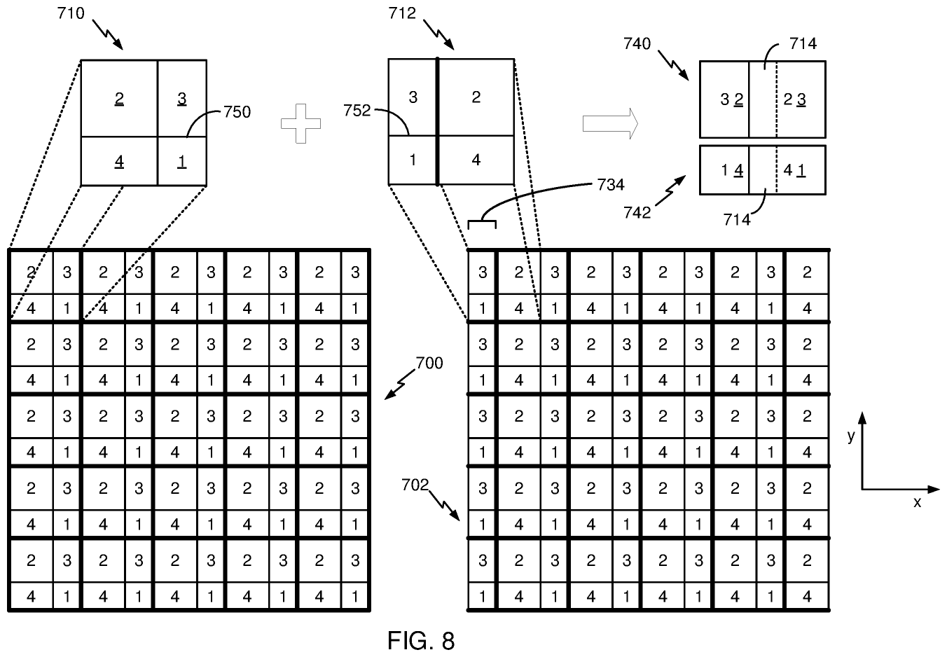

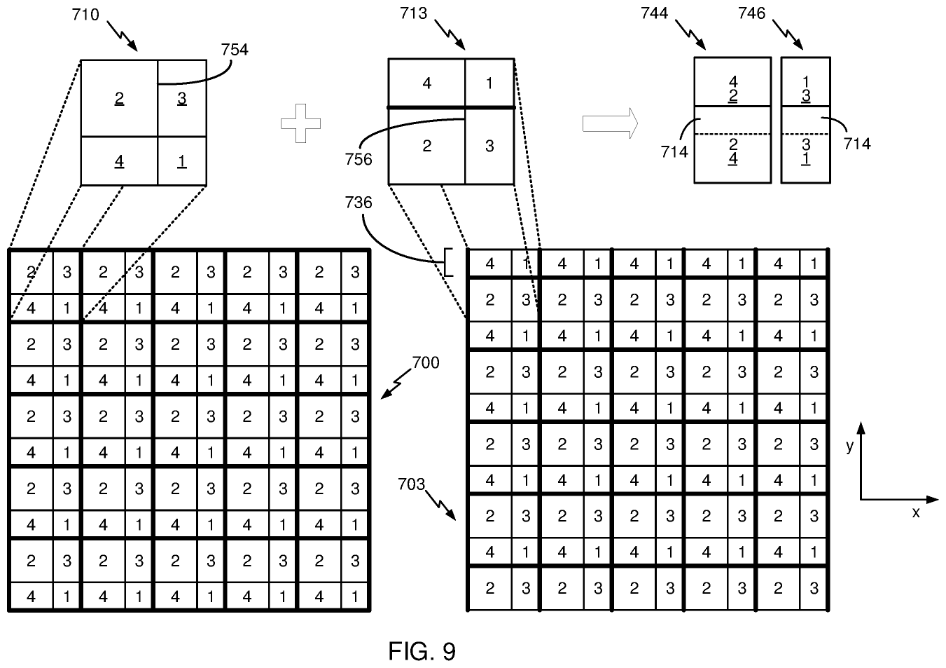

FIGS. 8 and 9 illustrate techniques for generating different types of heterogeneous dice by offsetting a single set of mask patterns and cutting the resulting bonded wafer stack and/or dice along the x-direction or the y-direction, according to several examples. As shown in FIG. 8, a third set of dice 712 are produced by stepping the set of mask patterns across a wafer 702 beginning at a starting position that is offset 734 in the x-direction (e.g., by approximately two-thirds of the total length of a die 710, 712). The first wafer 700 and second wafer 702 are then stacked on top of one another and bonded (e.g., via hybrid oxide bonding).

The bonded wafer stack (including the first wafer 700 and the second wafer 702) is then cut. For example, each die 710 may be cut along the outer boundaries depicted in FIG. 8 by thick, black lines, while simultaneously cutting wafer 702 to produce each die 712. Additionally, each resulting die stack 710, 712 may be further cut along an inner, horizontal boundary 750 of the set of mask patterns located between sub-dice 720 included in the die 710 while simultaneously cutting each die 712 along an inner. horizontal boundary 752 of the set of mask patterns located between sub-dice 720 included in die 712 to produce two 3D die stacks 740, 742.

The 3D die stacks 740, 742 include vertical alignment regions 714 at which sub-dice 720 disposed on different sides of the dice overlap, enabling high-bandwidth communication (e.g., by hybrid oxide bonding logic sub-regions 312 and/or regions 322 included in the sub-dice 720) between the sub-dice 720. In FIG. 8, the lower sub-dice 720 included in 3D die stacks 740, 742 are denoted by underlining the sub-dice numbers (e.g., 1, 2, 3, 4), and the boundaries between the lower sub-dice 720 are denoted by dotted lines.

As shown in FIG. 9, a fourth set of dice 713 are produced by stepping the set of mask patterns across a wafer 703 beginning at a starting position that is offset 736 in the y-direction (e.g., by approximately two-thirds of the total length of a die 710, 713). The first wafer 700 and second wafer 703 are then stacked on top of one another and bonded.

The bonded wafer stack (including the first wafer 700 and the second wafer 703) is then cut. For example, each die 710 may be cut along the outer boundaries depicted in FIG. 9 by thick, black lines, while simultaneously cutting wafer 703 to produce each die 713. Additionally, each resulting die stack 710, 713 may be further cut along an inner, vertical boundary 754 of the set of mask patterns located between sub-dice 720, while simultaneously cutting each die 713 along an inner, vertical boundary 756 of the set of mask patterns located between sub-dice 720 included in die 713 to produce two 3D die stacks 744, 746.

The 3D die stacks 744, 746 include vertical alignment regions 714 at which sub-dice 720 disposed on different sides of the dice overlap, enabling high-bandwidth communication (e.g., by hybrid oxide bonding logic sub-regions 312 and/or regions 322 included in the sub-dice 720) between the sub-dice 720. In FIG. 9, the lower sub-dice 720 included in 3D die stacks 744, 746 are denoted by underlining the sub-dice numbers (e.g., 1, 2, 3, 4), and the boundaries between the lower sub-dice 720 are denoted by dotted lines.

Although each of FIGS. 7-9 illustrate 3D die stacks including only two heterogeneous dice, in various embodiments, each 3D die stack may include any number of layers of heterogeneous dice. For example, with respect to FIG. 7, 3D die stack 739 could include multiple (e.g., 3, 4, 5, 8, 10, etc.), alternating layers of dice 710 and dice 711. In another example, 3D die stack 739 could include multiple layers that include the same die (e.g., 710) with a different die (e.g., 711) stacked on top of the multiple layers. Similar configurations may be implemented with respect to the 3D die stacks illustrated in FIGS. 8 and 9. Additionally, although FIGS. 7-9 illustrate wafers and dice being cut along certain boundaries, in various embodiments, cutting may be performed along any boundary located between sub-dice (e.g., an inner boundary defined with a set of mask patterns and/or an outer boundary defined by a perimeter of the set of mask patterns, denoted by thicker lines in FIGS. 7-9).

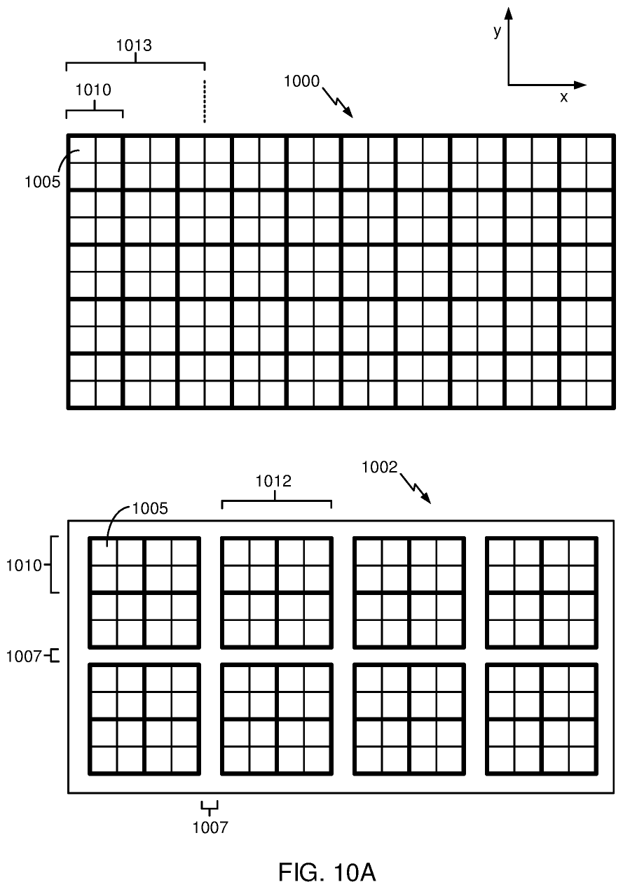

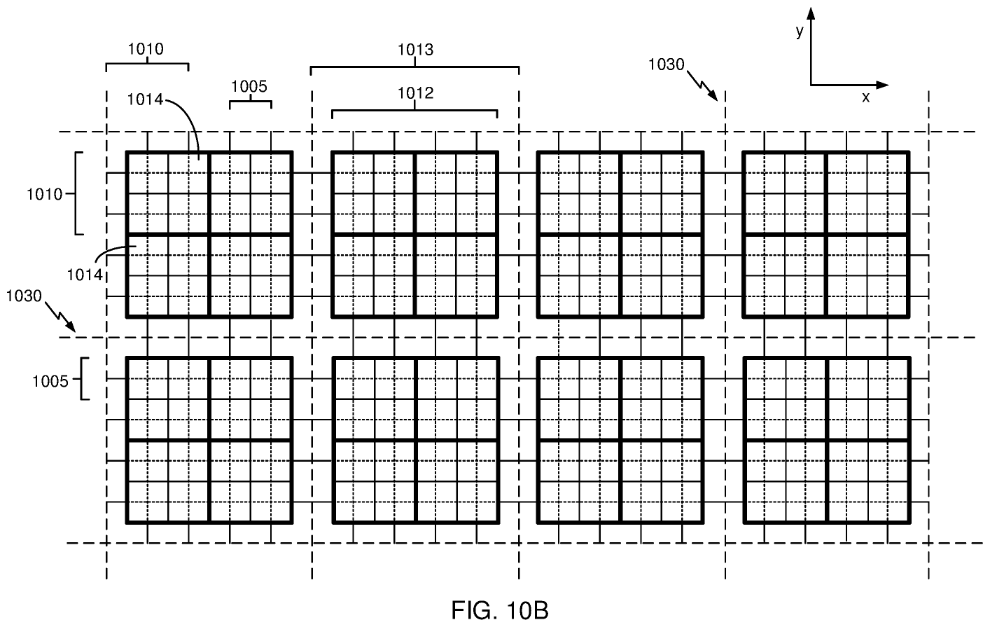

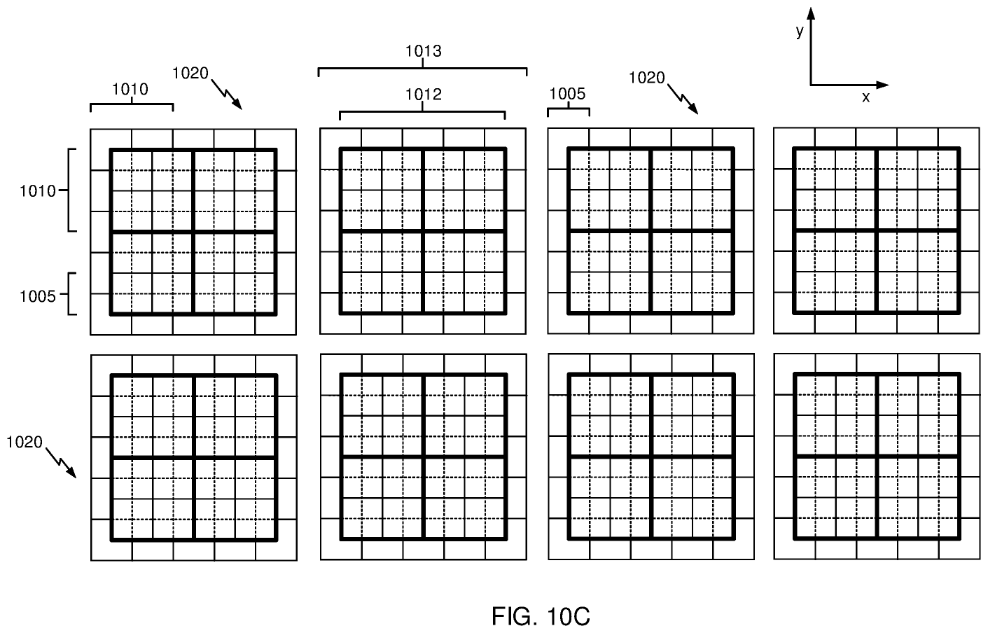

FIGS. 10A-10C illustrate a technique for generating large-scale 3D die stacks 1020 by offsetting a single set of mask patterns, according to an example. As shown, a first wafer 1000 includes a first set of dice 1010, where each die 1010 includes a set of four sub-dice 1005. As further shown, a second wafer 1002 includes a second set of dice 1010, where each die 1010 includes the same set of sub-dice 1005. In various embodiments, each sub-die 1005 defined by the set of mask patterns is an independent IC, such as a SoC 100, PL die 310, compute die 320, or I/O die 330. Although the first wafer 1000 and second wafer 1002 are shown as having a rectangular shape for simplicity of illustration, any wafer shape or size (e.g., circular) may be implemented. Additionally, each die 1010 may include any number of sub-dice 1005.

In various embodiments, the set of mask patterns is stepped across the first wafer 1000 beginning at a first starting position and stepped across the second wafer 1002 beginning at a second starting position that is offset from the first starting position in at least one of the x-direction and the y-direction (e.g., offset by half a length of a sub-die 1005 included in the die 1010). Additionally, the set of mask patterns may be stepped across the second wafer 1002 such that gaps 1007 exist between sets 1012 of dice 1010 (e.g., between each 2×2 set 1012 of dice 1010 that includes 4×4 sub-dice 1005).

As shown in FIG. 10B, the sets 1012 of dice 1010 are offset from and stacked on top of the dice 1010 included in the first wafer 1000. In some embodiments, the sets 1012 of dice 1010 are first cut from the second wafer 1002 and then stacked on top of the dice 1010 included in the first wafer 1000 in the offset manner shown in FIG. 10B. In other embodiments, the sets 1012 of dice 1010 are stacked on top of the dice 1010 included in the first wafer 1000 by stacking the second wafer 1002 on top of the first wafer (or by stacking the first wafer 1000 on top of the second wafer 1002).

The first wafer 1000 may be cut along boundaries 1030—either before or after stacking the sets 1012 of dice 1010 on top of the dice 1010 included in the first wafer 1000—to produce 3D die stacks 1020, shown in FIG. 10C. As shown in FIG. 10C, the 3D die stacks 1020 include a lower layer having a set 1013 of 5×5 sub-dice 1005 and an upper layer having a set 1012 of 4×4 sub-dice 1005. The 3D die stacks 1020 include vertical alignment regions 1014 at which the offset sub-dice 1005 overlap, enabling high-bandwidth communication (e.g., by hybrid oxide bonding logic sub-regions 312 and/or regions 322 included in the sub-dice 1005) between the sub-dice 1005 and between adjacent dice 1010.

Although FIG. 10C illustrates that each 3D die stack 1020 includes only two layers of dice 1010, in various embodiments, each 3D die stack 1020 may include any number of layers of dice 1010. For example, 3D die stack 1020 could include multiple (e.g., 3, 4, 5, 8, 10, etc.), alternating layers of sets 1013 of dice 1010 (e.g., 5×5 sub-dice 1005) from the first wafer 1000 and sets 1012 of dice 1010 (e.g., 4×4 sub-dice 1005) from the second wafer 1002. In another example, 3D die stack 1020 could include multiple layers of sets 1013 of dice 1010 that are aligned with one another (e.g., 3 layers, 4 layers, 5 layers etc.), with a set 1012 of dice 1010 (e.g., 711) stacked on top of the multiple layers. In such embodiments, an offset between the set 1012 of dice 1010 and the top set 1013 of dice 1010 would enable high-bandwidth communication (e.g., via vertical alignment regions 1014) between the columns of sub-dice 1005 included in the sets 1012 of dice 1010.

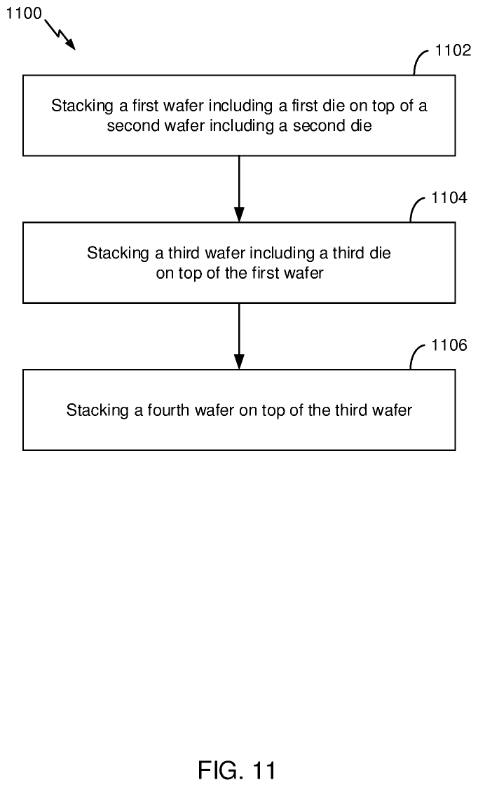

FIG. 11 is a flowchart of a method 1100 for producing a 3D die stack, according to an example. For ease of explanation, the method 1100 is discussed in tandem with the 3D die stacks illustrated in FIGS. 1-6.

At block 1102, a first wafer (e.g., 311-2, 411-2) including a first die (e.g., 310, 410, etc.) is stacked on top of second wafer (e.g., 311-3, 411-3) including a second die (e.g., 312, 410, etc.), where the first die is offset from the second die in at least one of an x-direction and a y-direction. In some embodiments, the first wafer includes a first plurality of dice (e.g., 310, 410, etc.) and the second wafer includes a second plurality of dice (e.g., 312, 410, etc.).

At block 1104, a third wafer (e.g., 311-1, 411-1) including a third die (e.g., 312, 410, etc.) is stacked on top of the first wafer, where the third die is offset from the first die in at least one of the x-direction and the y-direction. In some embodiments, the third wafer includes a third plurality of dice (e.g., 312, 410, etc.)

At block 1106, a fourth wafer (e.g., 321) including one or more dice (e.g., 320) is stacked on top of the third wafer, where each of the one or more dice is offset from the third die in at least one of the x-direction and the y-direction. In some embodiments, the fourth wafer includes a plurality of compute dice (e.g., 320). The method 1100 may then be optionally repeated for a number of additional wafers including, for example, PL dice, CPU dice, GPU dice, SoC dice, ASIC dice, compute dice, and/or I/O dice (e.g., 330).

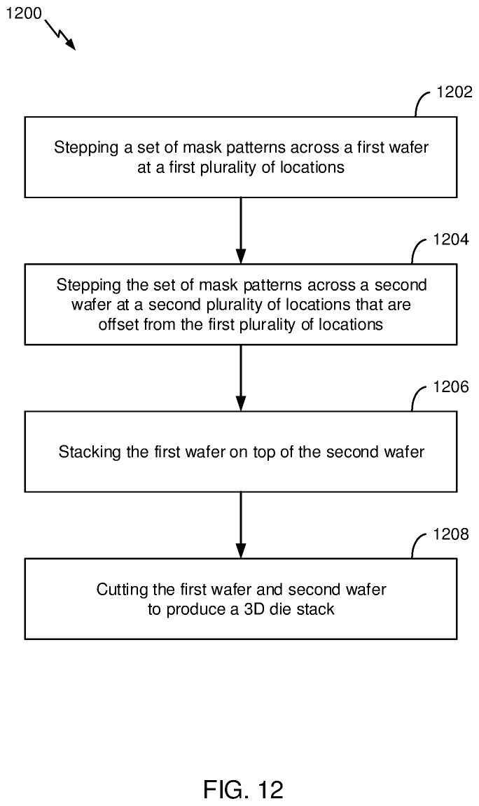

FIG. 12 is a flowchart of a method 1200 for producing a 3D die stack by stepping a set of mask patterns in an offset manner, according to an example. For ease of explanation, the method 1200 is discussed in tandem with the 3D die stacks illustrated in FIGS. 7-9 and 10A-10C.

At block 1202, a set of mask patterns is stepped across a first wafer (e.g., 700) at a first plurality of locations. At block 1204, the set of mask patterns is stepped across a second wafer (e.g., 701, 702, 703) at a second plurality of locations that are offset from the first plurality of locations (e.g., by two-thirds of the length of a die, by half the length of a die, etc.).

At block 1206, the first wafer is stacked on top of the second wafer and bonded to the second wafer (e.g., via hybrid oxide bonding). At block 1208, the bonded wafer stack (including the first wafer and the second wafer) is cut at a first boundary (e.g., an outer boundary) corresponding to an outer perimeter (e.g., denoted by a thicker line in FIGS. 7-9) of the set of mask patterns to generate a first die (e.g., 710) while simultaneously cutting the second wafer at a second boundary defined within the set of mask patterns to generate a second die (e.g., 711, 712, 713) to produce a 3D die stack (e.g., 739, 740, 742, 744, 746). In some embodiments, the second boundary is an inner boundary (e.g., 750, 752, 754, 756) defined within the set of mask patterns.

In the preceding, reference is made to embodiments presented in this disclosure. However, the scope of the present disclosure is not limited to specific described embodiments. Instead, any combination of the described features and elements, whether related to different embodiments or not, is contemplated to implement and practice contemplated embodiments. Furthermore, although embodiments disclosed herein may achieve advantages over other possible solutions or over the prior art, whether or not a particular advantage is achieved by a given embodiment is not limiting of the scope of the present disclosure. Thus, the preceding aspects, features, embodiments and advantages are merely illustrative and are not considered elements or limitations of the appended claims except where explicitly recited in a claim(s).

As will be appreciated by one skilled in the art, the embodiments disclosed herein may be embodied as a system, method or computer program product. Accordingly, aspects may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, aspects may take the form of a computer program product embodied in one or more computer readable medium(s) having computer readable program code embodied thereon.

Any combination of one or more computer readable medium(s) may be utilized. The computer readable medium may be a computer readable signal medium or a computer readable storage medium. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer readable storage medium is any tangible medium that can contain, or store a program for use by or in connection with an instruction execution system, apparatus or device.

A computer readable signal medium may include a propagated data signal with computer readable program code embodied therein, for example, in baseband or as part of a carrier wave. Such a propagated signal may take any of a variety of forms, including, but not limited to, electro-magnetic, optical, or any suitable combination thereof. A computer readable signal medium may be any computer readable medium that is not a computer readable storage medium and that can communicate, propagate, or transport a program for use by or in connection with an instruction execution system, apparatus, or device.

Program code embodied on a computer readable medium may be transmitted using any appropriate medium, including but not limited to wireless, wireline, optical fiber cable, RF, etc., or any suitable combination of the foregoing.

Computer program code for carrying out operations for aspects of the present disclosure may be written in any combination of one or more programming languages, including an object oriented programming language such as Java, Smalltalk, C++ or the like and conventional procedural programming languages, such as the “C” programming language or similar programming languages. The program code may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

Aspects of the present disclosure are described below with reference to flowchart illustrations and/or block diagrams of methods, apparatus (systems) and computer program products according to embodiments presented in this disclosure. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks.

These computer program instructions may also be stored in a computer readable medium that can direct a computer, other programmable data processing apparatus, or other devices to function in a particular manner, such that the instructions stored in the computer readable medium produce an article of manufacture including instructions which implement the function/act specified in the flowchart and/or block diagram block or blocks.

The computer program instructions may also be loaded onto a computer, other programmable data processing apparatus, or other devices to cause a series of operational steps to be performed on the computer, other programmable apparatus or other devices to produce a computer implemented process such that the instructions which execute on the computer or other programmable apparatus provide processes for implementing the functions/acts specified in the flowchart and/or block diagram block or blocks.

The flowchart and block diagrams in the Figures illustrate the architecture, functionality, and operation of possible implementations of systems, methods, and computer program products according to various examples of the present invention. In this regard, each block in the flowchart or block diagrams may represent a module, segment, or portion of instructions, which comprises one or more executable instructions for implementing the specified logical function(s). In some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

While the foregoing is directed to specific examples, other and further examples may be devised without departing from the basic scope thereof, and the scope thereof is determined by the claims that follow.

What is claimed is:

1. A method of producing a three-dimensional (3D) die stack, comprising:
stacking a first die on top of a second die, wherein the first die is offset from the second die in at least one of an x-direction and a y-direction, and a first routing sub-region of the first die aligns with a second routing sub-region of the second die; and
stacking a third die on top of the second die, wherein the third die is offset from the second die in at least one of the x-direction and the y-direction, and a third routing sub-region of the third die aligns with a fourth routing sub-region of the second die.

2. The method of claim 1, wherein the first routing sub-region of the first die communicates with the third routing sub-region of the third die via the second routing sub-region and the fourth routing sub-region.

3. The method of claim 2, wherein the first die does not directly communicate with the third die.

4. The method of claim 1, wherein the first die, the second die, and the third die comprise programmable logic (PL), and the first routing sub-region, the second routing sub-region, the third routing sub-region, and the fourth routing sub-region comprise fabric sub-regions.

5. The method of claim 1, further comprising stacking a fourth die on top of the first die and the third die, wherein a fifth routing sub-region of the fourth die aligns with at least a portion of the second routing sub-region of the second die, and a sixth routing sub-region of the fourth die aligns with at least a portion of the fourth routing sub-region of the second die, and wherein the fifth routing sub-region of the fourth die communicates with the second routing sub-region via the first routing sub-region of the first die, and the sixth routing sub-region of the fourth die communicates with the fourth routing sub-region via the third routing sub-region of the third die.

6. The method of claim 1, further comprising stacking the second die on an input/output (I/O) die, wherein the second die is offset from the I/O die in at least one of the x-direction and the y-direction, and a fifth routing sub-region of the I/O die aligns with the second routing sub-region of the second die.

7. The method of claim 1, wherein the first die, the second die, and the third die comprise at least one of a central processing unit (CPU) die, a graphics processing unit (GPU) die, a programmable logic (PL) die, a system-on-chip (SoC) die, an application-specific integrated circuit (ASIC) die, and a memory die.

8. The method of claim 7, wherein one or more die layers are disposed between the first die and the second die.

9. The method of claim 1, wherein stacking the first die on top of the second die comprises hybrid oxide bonding a first wafer comprising the first die to a second wafer comprising the second die, and stacking the third die on top of the second die comprises hybrid oxide bonding a third wafer comprising the third die to the second wafer.

10. The method of claim 1, wherein the die is included in a first wafer comprising a first plurality of dice, and the second die is included in a second wafer comprising a second plurality of dice, wherein each die included in the first plurality of dice is offset from each die included in the second plurality of dice in at least one of the x-direction and the y-direction, and at least one routing sub-region of each die included in the first plurality of dice aligns with at least one routing sub-region of a die included in the second plurality of dice.

11. The method of claim 1, wherein a pitch of electrical connections between (i) a bottom of the first die and a top of the second die, and (ii) between a bottom of the third die and the top of the second die is less than 5 microns.

12. The method of claim 1, wherein the first routing sub-region comprises a first field-programmable gate array (FPGA) fabric, the second routing sub-region comprises a second FPGA fabric, the third routing sub-region comprises a third FPGA fabric, and the fourth routing sub-region comprises a fourth FPGA fabric.

13. A three-dimensional (3D) die stack, comprising:
a first die stacked on top of a second die, wherein the first die is offset from the second die in at least one of an x-direction and a y-direction, and a first routing sub-region of the first die aligns with a second routing sub-region of the second die; and
a third die stacked on top of the second die, wherein the third die is offset from the second die in at least one of the x-direction and the y-direction, and a third routing sub-region of the third die aligns with a fourth routing sub-region of the second die.

14. The 3D die stack of claim 13, wherein the first routing sub-region of the first die communicates with the third routing sub-region of the third die via the second routing sub-region and the fourth routing sub-region.

15. The 3D die stack of claim 14, wherein the first die does not directly communicate with the third die.

16. The 3D die stack of claim 13, wherein the first die, the second die, and the third die comprise programmable logic (PL), and the first routing sub-region, the second routing sub-region, the third routing sub-region, and the fourth routing sub-region comprise fabric sub-regions.

17. The 3D die stack of claim 13, wherein the first die, the second die, and the third die comprise at least one of a central processing unit (CPU) die, a graphics processing unit (GPU) die, a programmable logic (PL) die, a system-on-chip (SoC) die, an application-specific integrated circuit (ASIC) die, and a memory die.

18. The 3D die stack of claim 17, wherein one or more die layers are disposed between the first die and the second die.

19. The 3D die stack of claim 13, wherein the first die is included in a first wafer comprising a first plurality of dice, and the second die is included in a second wafer comprising a second plurality of dice, wherein each die included in the first plurality of dice is offset from each die included in the second plurality of dice in at least one of the x-direction and the y-direction, and at least one routing sub-region of each die included in the first plurality of dice aligns with at least one routing sub-region of a die included in the second plurality of dice.

20. A computing system, comprising:
a memory; and
a three-dimensional (3D) die stack coupled to the memory and comprising:
a first die stacked on top of a second die, wherein the first die is offset from the second die in at least one of an x-direction and a y-direction, and a first routing sub-region of the first die aligns with a second routing sub-region of the second die; and
a third die stacked on top of the second die, wherein the third die is offset from the second die in at least one of the x-direction and the y-direction, and a third routing sub-region of the third die aligns with a fourth routing sub-region of the second die.
